(19) United States
(12) Patent Application Publication
(10) Pub. No.: US 2009/0173527 A1
(43) Pub. Date: Jul. 9, 2009

(54) Method for Integrating Functional Nanostructures Into Microelectric and Nanoelectric circuits

(76) Inventors: Annegret Benke, Freital (DE); Gerald Eckstein, München (DE); Oliver Jost, Dresden (DE); Michael Mertig, Dresden (DE); Daniel Sickert, München (DE); Sebastian Taeger, Dresden (DE)

Correspondence Address: STAAS & HALSEY LLP, SUITE 700, 1201 NEW YORK AVENUE, N.W., WASHINGTON, DC, 20005, US

(21) Appl. No.: 11/990,265

(22) PCT Filed: Jul. 27, 2006
(86) PCT No.: PCT/EP2006/064761

§ 371 Date: Mar. 3, 2009

(30) Foreign Application Priority Data
Aug. 11, 2005 (DE) 10 2005 038 121.9

(51) Int. Cl. H05K 1/11; C25B 7/00

(52) U.S. Cl. 174/261; 204/547; 977/932; 977/842

(57) ABSTRACT

A nanostructure is provided on a substrate by forming at least one multi-electrode arrangement on the substrate, wherein said electrodes comprise respective electrode areas projected with respect to the opposite electrode ends which extend along a line in such a way that the adjacent ends produce a respectively frequency time-variable potential difference. A suspension of nano-object such as nanotubes, nanowires and/or carbon nanotubes is produced and then transferred to the substrate between the adjacent ends. The assembly of respective individual nano-objects is dielectrophoreticly deposited on the line between said adjacent ends, and the assembly of respective nano-objects is fused in the area of the ends in such a way that the nanostructure is formed.

### CROSS REFERENCE TO RELATED APPLICATIONS

This application is based on and hereby claims priority to German Application No. 10 2005 038 121.9 filed on Aug. 11, 2005 and PCT Application No. PCT/EP2006/06471 filed on Jul. 27, 2006, the contents of which are hereby incorporated by reference.

### BACKGROUND

Nanoobjects such as carbon nanotubes (CNTs) and other nanotubes or more specifically nanowires possess remarkable electrical, optical and mechanical properties which can be used for a variety of applications in electronics, sensor systems, micro/nano mechanics and micro/nano systems engineering. For these applications it is necessary to selectively position, fix and contact the nanotubes or more specifically nanowires, or the nanoobjects in general, on substrates individually or as a batch. For many applications it is also necessary to produce conducting or semiconducting channels which are longer than the nanotubes or nanowires used therefor.

In addition, the known methods for producing carbon nanotubes (CNTs) result in a mixture of metallic and semiconducting nanotubes, so that the yield for components which require either metallic or semiconducting nanotubes is compromised.

Various known methods are used for producing nanoobjects on substrates. For example, methods exist for growing nanotubes or more specifically nanowires in-situ (e.g. from silicon) on patterned catalysts. In this case the substrate has to be heated to a temperature of 500° C. The temperatures therefore required are very high. Another known method is based on nonspecific deposition of nanotubes or more specifically nanowires or comparable nanoobjects on the substrate. These objects are then localized and contacted. This method is only suitable for experimental testing of a small number of nanoscale objects. According to another known method, functional groups are used for depositing modified nanoobjects on complementary functionalized surfaces and oriented by a flow cell.

The disadvantage of the known methods is that it is very difficult to build up branched structures and to span long sections many times the length of an individual nanoobject.

### SUMMARY

One potential object is therefore to provide a method for producing nanoobjects on a substrate, whereby nanostructures which are many times the length of an individual nanoobject and/or branched are produced in a simple, fast and versatile manner. In particular, the aim is to produce nanostructures which can be integrated into complex networks of known design.

The inventors propose a method that uses a multi-electrode arrangement in which electrodes have projecting regions with ends facing away from the electrode. These ends are disposed along a line in such a way that adjacent ends each produce a potential difference which varies with a frequency over time.

According to the present invention, nanoobjects such as nanotubes or more specifically nanowires are first converted to a stable or metastable suspension using organic solvents, surface active substances such as tensides or deoxyribonucleic acid (DNA) or after chemical functionalization. In this form the nanoobjects are transferred as droplets or in a continuously flowing manner to the electrode structure disposed on a substrate or more precisely to the multi-electrode arrangement disposed on a substrate.

The proposed method envisions depositing nanoobjects, such as nanotubes and nanowires, for creating nanostructures by dielectrophoresis in the specially designed electrode structures or rather multi-electrode arrangements. The known dielectrophoresis method is used for manipulating biological cells and metallic clusters. The deposition of e.g. carbon nanotubes between individual electrode gaps is now to be optimized. According to the proposed method, long and branched structures of nanoobjects are now built up. By applying a time-varying potential to electrodes, inhomogeneous electric fields are produced. By selectively selecting the suspension medium, the potential—in particular between 10³ and 10⁹ Vm⁻¹—and the field frequency, in particular between a few kHz and several GHz, the nanoobjects are attracted in the direction of the field gradient, i.e. toward the electrodes.

Separate nanoobject clusters are first dielectrophoretically deposited independently of one another between adjacent ends of projecting electrode regions. A nanoobject cluster is formed from a plurality of jointly deposited nanoobjects. After a particular deposition time, these nanoobject clusters grow together in the region of the ends to form at least one nanostructure. Nanoobject cluster growth takes place in particular along the shortest distances between adjacent ends, which generate a time-varying potential difference.

According to an advantageous embodiment, the projecting electrode regions are electrode fingers. Tips of the electrode fingers constitute the ends.

According to another advantageous embodiment, the multi-electrode arrangement has only two electrodes.

According to an advantageous embodiment, the shape of the nanostructure produced is defined by the disposition of the multi-electrode arrangement or by the design of the multi-electrode arrangement.

For example, by branching the sequence of ends, a correspondingly branched nanostructure can be produced.

According to another preferred embodiment, the nanostructures produced can be easily integrated into in micro- and/or nanoelectric circuits or networks. This means that the method is compatible with known patterning processes. For example, post-CMOS compatibility is provided.

According to another advantageous embodiment, the nanostructures produced are additionally patterned and/or contacted and/or morphologically modified. This takes place according to the purpose of the nanostructure.

According to another advantageous embodiment, by suitably selecting the electrical properties of the suspension and/or the frequency, conducting, semiconducting and/or mixed conducting nanoobjects and/or nanostructures produced therewith can be created.

According to another advantageous embodiment, a dielectric layer is disposed on the multi-electrode arrangement applied to the substrate, the nanostructure being able to be created on the dielectric layer. This nanostructure can be removed from the dielectric layer and applied to other substrates.

According to another advantageous embodiment, by suitably selecting the spacing between adjacent ends, the required potential difference can be kept small. At the same time the required potential difference is intended to enable complete deposition of the nanoobjects between the individual ends.

According to another advantageous embodiment, the electrodes of a potential are capacitively coupled to the associated potential source via the substrate. This means that the frequency-dependent current is limited after the short-circuiting of first projecting electrode regions or more specifically of first electrode fingers by the nanoobjects or more specifically nanoobject clusters.

According to another advantageous embodiment, separate electrodes of a potential can be controlled independently of one another.

According to another advantageous embodiment, the electrodes are buried in the substrate and/or contacted through the substrate from the side of the substrate facing away from the electrode. This means that the nanostructures produced lie flat and directly on the substrate also in the region of the electrodes.

According to another advantageous embodiment, the electrodes are produced in planar technology and/or contacted in a stepwise manner. Planar technology methods are well known, attention being drawn in particular to the so-called “SiPLIT technology” (see e.g. patent application DE 10147935.2). This means that reliable connection and contacting matched to nanostructure production are possible.

According to another advantageous embodiment, the multi-electrode arrangement or more precisely individual electrode regions are selectively removed. This advantageously enables short-circuits produced by nanoobjects or rather nanoobject clusters to be removed.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows the principle of dielectrophoretic deposition in conjunction with the creation of nanostructures;

FIG. 2 shows a first exemplary embodiment of a multi-electrode arrangement;

FIG. 3 shows a second exemplary embodiment of a multi-electrode arrangement;

FIG. 4 shows a third exemplary embodiment of a multi-electrode arrangement;

FIG. 5 shows a fourth exemplary embodiment of a multi-electrode arrangement;

FIG. 6 shows another exemplary embodiment of an arrangement for creating nanostructures.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

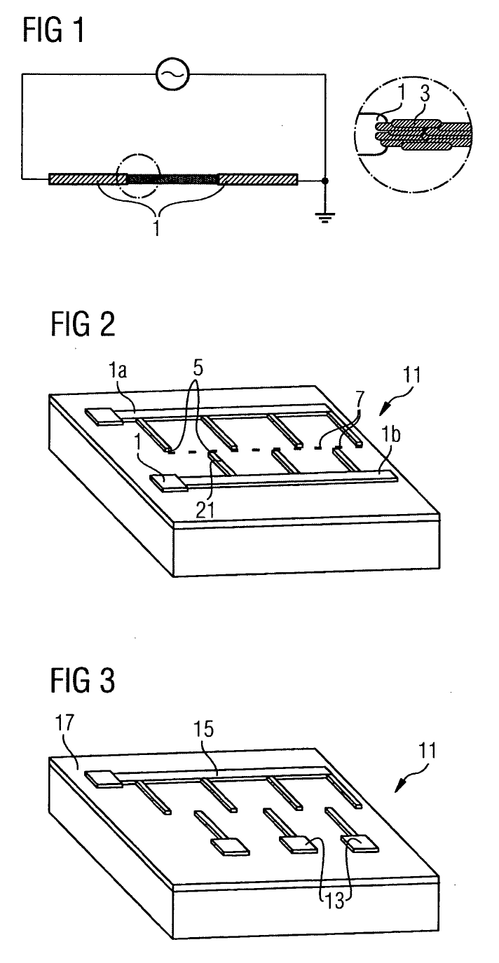

FIG. 1 illustrates the principle of dielectrophoretic deposition. The black area shown between the electrodes 1 (hatched area) is formed of deposited nanoobjects 3 such as carbon nanotubes which are disposed either individually or sequentially depending on the spacing of the electrodes 1, and which bridge electrode gaps. The more precise disposition of the carbon nanotubes is shown in the enlargement on the right. One electrode 1 is at ground potential, while the other electrode 1 is connected to a time-varying potential by an AC voltage source.

FIG. 2 shows a series of consecutive ends 5 which are produced by tips of electrode fingers 21 and between which separate nanoobject clusters 7 are deposited independently of one another. The ends 5 are the ends 5 (facing away from the electrode) of projecting electrode regions. The projecting electrode regions can be provided as electrode fingers 21. The electrode structure shown here or more precisely the multi-electrode arrangement 11 shown here enables nanostructures 9 of any length to be built up, e.g. in the form of tracks containing nanoobjects 3. The upper electrode 1a is e.g. at a high potential, while the lower electrode 1b is at ground potential. The electrodes 1a and 1b have the electrode fingers 21. The tips of said electrode fingers 21 correspond to the ends 5. Nanoobjects 3 or more precisely nanoobject clusters 7 are deposited in the area of the line between two adjacent ends 5. One advantage of this multi-electrode arrangement 11 is that the voltage required for depositing the nanoobjects 3 can be limited. The short spacings between the ends 5 mean that the field strength required for deposition is achieved even at moderate voltages.

FIG. 3 shows a second exemplary embodiment of an advantageous multi-electrode arrangement 11. In this example, the individual counter-electrodes 13 are consecutively contacted to the upper one-piece electrode 15 and electrically connected to the ground potential source during production. This means that the individual counter-electrodes 13 can be controlled independently of one another. The upper electrode 15 which is created as a coherent entity, i.e. as a one-piece electrode 15, is at a signal potential. The signal potential is produced by a voltage source as shown in FIG. 1. The electrodes 1 can be created e.g. on silicon in planar technology. These electrodes 13 can be contacted in a stepwise manner. The stepwise contacting enables the nanoobjects 3 or nanoobject clusters 7 to be consecutively deposited between the electrodes 13 and 15, i.e. the nanoobjects 3 or nanoobject clusters 7 are not deposited simultaneously. According to a variant, “buried” and/or through-via electrodes can be implemented, with the result that the nanoobjects 3 are everywhere directly on a substrate 17, even in the vicinity of the electrodes. This prevents “rising” or “thickening” of the nanostructures 9 near the electrodes and on the electrodes 13 or 15.

According to a third exemplary embodiment, what are termed “floating” electrodes can be used which are capacitively coupled to a potential.

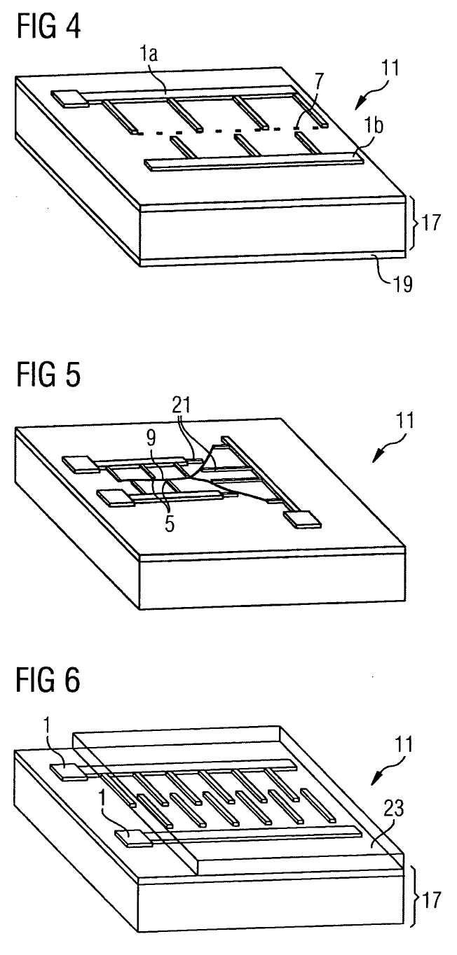

According to the multi-electrode arrangement 11 in FIG. 4, long tracks of nanoobjects 3 can be built up, as already shown in connection with FIG. 2. The upper electrode 1a illustrated here is again at a high potential, while the lower electrode 1b shown here is connected to ground potential 19 by capacitive coupling via the substrate 17. The capacitive coupling of the electrodes to ground potential limits the current as a function of frequency after the short-circuiting of first electrode fingers 21 of the multi-electrode arrangement 11.

FIG. 5 shows a fourth exemplary embodiment of a multi-electrode arrangement 11 wherein the electrode fingers 19 of the electrode arrangement 11 are disposed in such a way that branched tracks of nanoobjects 3 can be built up. This means that by suitable design it is possible for branched nanostructures 9 of nanoobjects 3 to be built up, in particular in the form of tracks. The nanostructures 9 produced in this way of nanoobjects 3 can be photolithographically patterned, metallically contacted or morphologically modified e.g. by chemical or physical etching processes. The multi-electrode arrangement 11 can be selectively removed when deposition is complete in order to avoid short-circuiting of the electrodes 1. A nanostructure 9 is created by the deposition of separate nanoobject clusters 7 between adjacent ends 5 and the growing-together of the nanoobject clusters 7 taking place in the region of the ends 5. The above-described further processing of nanostructures 9 is possible for all the exemplary embodiments.

FIG. 6 shows another exemplary embodiment for creating a multi-electrode arrangement 11. According to this exemplary embodiment, the multi-electrode arrangement 11 is coated with a thin dielectric 23 which can be inorganic or organic. In this way a homogeneous and level surface 11 is produced above the multi-electrode arrangement. This facilitates removal of the nanostructure 9, either alone or in conjunction with the dielectric layer 23.

In this way nanostructures 9 can be imprinted onto other substrates. This imprinting can be effected e.g. by a stamping process whereby the multi-electrode arrangement 11 disposed on its substrate is used as the master stamp on which nanostructures 9 are created in each case and, when complete, are imprinted onto other substrates, i.e. dielectric coatings 23 of this kind permit simple removal of the deposited nanostructures 9 or their overprinting into target substrates, the multi-electrode arrangement 11 being reusable in each case.

Moreover, as shown in FIG. 6, a dielectric coating 23 prevents short-circuiting of electrodes 1 when electrode gaps are bridged by nanoobject clusters 7 or nanostructures 9, the multi-electrode arrangement 11 likewise being usable directly on the substrate 17. That is to say, by partially coating the multi-electrode arrangement 11 with a thin dielectric 23, direct contact between the electrodes 1 and the nanoobjects 3 can be prevented, thereby preventing a short-circuit when electrode gaps are bridged.

In all the exemplary embodiments, suitably selecting the field frequency and the electronic properties of the suspension medium allows selective deposition of particular nanoobjects 3 if they are present in a mixture. This enables, for example, metallic carbon nanotubes (CNTs) to be deposited in the multi-electrode arrangements 11 from a suspension likewise containing semiconducting CNTs. In this way, nanostructures 9 comprising exclusively metallic carbon nanotubes (CNTs) can be created e.g. in the form of tracks.

A major advantage of the proposed method and devices lies in the compatibility of the method with known microelectronics patterning methods and, in particular, in its post-CMOS compatibility because of processing at temperatures well below 450° C. The method allows versatile and rapid positioning and/or creation of nanoobject clusters 7 or nanostructures 9 in complex networks and orientation over distances in excess of their own length. The maximum voltage required for deposition of the nanoobjects 3 and nanoobject clusters 7 is reduced by the provisioning of a multi-electrode arrangement 11 with small electrode spacings or, as the case may be, small spacings between ends 5. Nanostructures 9 with any desired geometries and/or shapes can be created.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v DIRECTV, 69 USPQ2d 1865 (Fed. Cir. 2004).

1-16. (canceled)

17. A method for producing at least one nanostructure on a substrate, comprising:
forming a multi-electrode arrangement on the substrate, the multi-electrode arrangement including electrodes positioned on opposing sides of a line, the electrodes having projecting electrode regions that extend away from respective bodies of the electrodes and toward the line, such that along and in a vicinity of the line there exists a series of adjacent ends of opposing electrodes, each of the adjacent ends producing a potential difference that varies with a frequency over time;
producing a suspension containing nanoobjects selected from the group consisting of nanotubes, nanowires and carbon nanotubes;
transferring the suspension to the substrate between the adjacent ends;
dielectrophoretically depositing clusters of nanoobjects along the line between the adjacent ends; and
growing-together the clusters of nanoobject in the vicinity of the adjacent ends to thereby form the nanostructure.

18. The method as claimed in claim 17, wherein
on at least one side of the line, there are a plurality of electrodes, each electrode having a single projecting electrode region.

19. The method as claimed in claim 17, wherein
there is a single electrode on each side of the line, each electrode having a plurality of projecting electrode regions.

20. The method as claimed in claim 17, wherein
electrodes are positioned with adjacent ends defining a pattern of lines, and
the nanostructure has a shape defined by the pattern defined by the adjacent ends.

21. The method as claimed in claim 20, wherein
the adjacent ends define t a branching of the line, and
a branched nanostructure is produced.

22. The method as claimed in claim 17,
wherein the nanostructure is integrated into a micro- and/or nanoelectric circuit or network by integrating the multi-electrode arrangement into the micro- and/or nanoelectric circuit or network.

23. The method as claimed in claim 17, further comprising patterning the nanostructure with photolithography, bringing another object into electric contact with the nanostructure and/or morphologically modifying the nanostructure.

24. The method as claimed in claim 17, wherein
the clusters of nanoobjects are conducting and/or semiconducting, and
the clusters of nanoobjects have a conductivity defined by electrical properties of the suspension and/or of the frequency with which the potential difference varies.

25. The method as claimed in claim 17,
further comprising forming a dielectric layer on the multi-electrode arrangement and the substrate, the nanostructure being produced on the dielectric layer.

26. The method as claimed in claim 17, further comprising:
removing the dielectric layer and the nanostructure from the substrate; and
imprinting the nanostructure on another substrate.

27. The method as claimed in claim 17, wherein there is a small spacing between adjacent ends to minimize the potential difference required to deposit the clusters of nanoobjects.

28. The method as claimed in claim 17, wherein at least one of electrodes is capacitively coupled an associated potential source via the substrate to achieve the potential difference.

29. The method as claimed in claim 17, wherein the electrodes having potentials that are controlled independently of one another.

30. The method as claimed in claim 17, wherein the electrodes are buried in the substrate and/or electrically contacted through the substrate from a side of the substrate facing away from the electrodes.

31. The method as claimed in claim 17, wherein the electrodes are produced in planar technology and/or contacted in a stepwise manner.

32. The method as claimed in claim 17, wherein after forming the nanostructure, the multi-electrode arrangement is selectively removed.

33. A nanostructure, produced on a substrate by a method comprising:
forming a multi-electrode arrangement on the substrate, the multi-electrode arrangement including electrodes positioned on opposing sides of a line, the electrodes having projecting electrode regions that extend away from respective bodies of the electrodes and toward the line, such that along and in a vicinity of the line there exists a series of adjacent ends of opposing electrodes, each of the adjacent ends producing a potential difference that varies with a frequency over time;
producing a suspension containing nanoobjects selected from the group consisting of nanotubes, nanowires and carbon nanotubes;
transferring the suspension to the substrate between the adjacent ends;
dielectrophoretically depositing clusters of nanoobjects along the line between the adjacent ends; and
growing-together the clusters of nanoobject in the vicinity of the adjacent ends to thereby form the nanostructure.

34. A multi-electrode arrangement, comprising:
a substrate;
potential sources; and
electrodes positioned on opposing sides of a line on the substrate, the electrodes having projecting electrode regions that extend away from respective bodies of the electrodes and toward the line, such that along and in a vicinity of the line there exists a series of adjacent ends of opposing electrodes, each of the adjacent ends being associated with one of the potential sources to produce a potential difference that varies with a frequency over time.
